(19) United States
(12) Patent Application Publication
(10) Pub. No.: US 2017/0283945 A1
(43) Pub. Date: Oct. 5, 2017

(54) Substrate Processing Apparatus

(71) Applicant: Hitachi Kokusai Electric Inc., Tokyo (JP)

(72) Inventors: Takashi YAHATA, Toyama (JP); Satoshi TAKANO, Toyama (JP); Kazuyuki TOYODA, Toyama (JP); Shun MATSUI, Toyama (JP)

(21) Appl. No.: 15/203,460

(22) Filed: Jul. 6, 2016

(30) Foreign Application Priority Data
Mar. 29, 2016 (JP) 2016-065707

(51) Int. Cl. C23C 16/44; C23C 16/52; C23C 16/455; H01J 37/32; H01L 21/02

(52) U.S. Cl. CPC C23C 16/4405; H01J 37/32082; H01J 37/3244; H01J 37/32715; H01J 37/32862; H01L 21/0217; H01L 21/0228; C23C 16/45565; C23C 16/4412; H01J 37/32357; C23C 16/52; H01J 2237/334; H01J 2237/335

(57) ABSTRACT

A substrate processing apparatus includes: a process chamber where a substrate is processed; a substrate support, disposed in the process chamber, where the substrate is placed; a transfer chamber disposed under the process chamber; a partition dividing the process and transfer chambers; a first heating unit disposed in the substrate support to heat the substrate and the process chamber; a second heating unit disposed in the transfer chamber to heat the transfer chamber; a process gas supply unit to supply a process gas into the process chamber; a first cleaning gas supply unit to supply a cleaning gas into the process chamber; a second cleaning gas supply unit to supply the cleaning gas into the transfer chamber; and a control unit to control the first heating unit, the second heating unit, the process gas supply unit, the first cleaning gas supply unit and the second cleaning gas supply unit.

### CROSS REFERENCE TO RELATED APPLICATIONS

This application claims foreign priority under 35 U.S.C. §119(a)-(d) to Application No. JP 2016-065707 filed on Mar. 29, 2016, the entire contents of which are hereby incorporated by reference.

### TECHNICAL FIELD

The present disclosure relates to a substrate processing apparatus, a method of manufacturing a semiconductor device and a non-transitory computer-readable recording medium.

### BACKGROUND

As one of processes of manufacturing a semiconductor device, a processing process of forming a film by supplying a process gas and a reaction gas onto a substrate is performed.

### SUMMARY

Due to a temperature difference between a substrate process space and a substrate transfer space, unintended by-products are adhered to a side portion of the substrate transfer space in which a temperature is not controlled. A film may be detached from the by-products or particles may be generated therefrom.

Described herein is a technique in which reproducibility and stability of a process can be improved even though a substrate processing temperature becomes a high temperature.

According to one aspect, a substrate processing apparatus includes: a process chamber where a substrate is processed; a substrate support where the substrate is placed, the substrate support being disposed in the process chamber; a transfer chamber disposed under the process chamber; a partition dividing the process chamber and the transfer chamber; a first heating unit disposed in the substrate support and configured to heat the substrate and the process chamber; a second heating unit disposed in the transfer chamber and configured to heat the transfer chamber; a process gas supply unit configured to supply a process gas into the process chamber; a first cleaning gas supply unit configured to supply a cleaning gas into the process chamber; a second cleaning gas supply unit configured to supply the cleaning gas into the transfer chamber; and a control unit configured to control the first heating unit, the second heating unit, the process gas supply unit, the first cleaning gas supply unit and the second cleaning gas supply unit.

### BRIEF DESCRIPTION OF THE DRAWINGS

FIG. 1 is a vertical cross-sectional view schematically illustrating a substrate processing apparatus according to one embodiment described herein.

FIG. 2 is a diagram for describing a gas supply system according to one embodiment described herein.

FIG. 3 is a diagram schematically illustrating a configuration of a controller of a substrate processing system according to one embodiment described herein.

FIG. 4 is a flow diagram of a substrate processing process according to one embodiment described herein.

FIG. 5 is a sequence diagram of a substrate processing process according to one embodiment described herein.

FIG. 6 is a flow diagram of a cleaning process according to one embodiment described herein.

FIG. 7 is a diagram illustrating an example of setting a temperature in a process chamber of a cleaning process in a film forming process according to one embodiment described herein.

FIG. 8 is a diagram illustrating an example of setting a temperature in a transfer chamber of a cleaning process in a film forming process according to one embodiment described herein.

### DETAILED DESCRIPTION

### First Embodiment

### (1) Configuration of Substrate Processing Apparatus

A substrate processing apparatus according to a first embodiment will be described.

A substrate processing apparatus 100 according to the present embodiment will be described. The substrate processing apparatus 100 includes, for example, a single-wafer substrate processing apparatus. A process of manufacturing a semiconductor device is performed in the substrate processing apparatus 100.

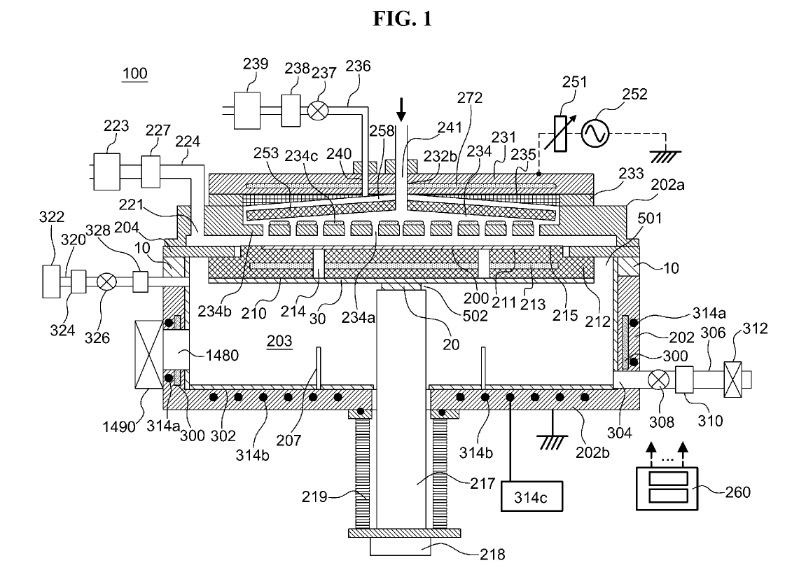

As illustrated in FIG. 1, the substrate processing apparatus 100 includes a process container 202. The process container 202 may be, for example, an airtight container having a circular and flat cross section. The process container 202 is formed of a metallic material such as aluminum (Al) and stainless steel (SUS) or quartz. A process space (process chamber) 201 in which a wafer 200 such as a silicon wafer serving as a substrate is processed and a transfer space (transfer chamber) 203 are provided in the process container 202. The process container 202 includes an upper container 202a and a lower container 202b. A partition 204 is installed between the upper container 202a and the lower container 202b. A space above the partition 204, which is surrounded by the upper container 202a, is referred to as the process space 201 (referred to as a process chamber) and a space under the partition 204, which is surrounded by the lower container 202b, is referred to as the transfer chamber 203.

A substrate loading and unloading port 1480 disposed adjacent to a gate valve 1490 is installed on a side surface of the lower container 202b. The wafer 200 moves between a transfer chamber (not illustrated) and the transfer chamber 203 through the substrate loading and unloading port 1480. Lift pins 207 are installed at a bottom portion of the lower container 202b. The lower container 202b is grounded.

When the upper container 202a is formed of quartz, a coefficient of thermal expansion of quartz may be 6×10⁻⁷/° C. When a difference ΔT between a low temperature and a high temperature is 300° C., the upper container 202a may extend from about 0.05 mm to 0.4 mm. When the lower container 202b is formed of aluminum, a coefficient of thermal expansion of aluminum may be 23×10⁻⁶/° C. When a difference ΔT between a low temperature and a high temperature is 300° C., the lower container 202b may extend from about 2.0 mm to 14 mm. An extension length ΔL is calculated by L×α×ΔT (where L denotes a length of a material in millimeters, a denotes a thermal expansion coefficient per degree (° C.) and ΔT denotes a temperature difference in degrees (° C.)).

As described above, the extension length (change amount) depends upon the material. A central position of a substrate placement unit 212 is different from a central position of a shower head 234 (position in an X-axis direction and position in a Y-axis direction) due to a difference of the change amount. Therefore, there is a problem in that process uniformity is reduced.

There is a problem in that a distance between a central position of the transfer chamber 203 and a central position of the process chamber 201 is increased and the wafer 200 may not be transferred to a center of a placement surface 211.

Since a distance between the placement surface 211 and a distribution plate 234b is changed according to a difference between extension lengths (change amount) in a direction (Z-axis direction) perpendicular to the substrate placement unit 212, there is a problem in that an exhaustion conductance of the process chamber 201 or an exhaustion conductance from the process chamber 201 to an exhaust port 221 is changed and thus process uniformity is reduced.

There is a problem in that a gas supplied into the process chamber 201 is introduced into the transfer chamber 203 and thus an unintended reaction occurs in the transfer chamber 203. Problems such as adhesion of by-products generated by an unintended reaction to a member in the transfer chamber 203, formation of a film by the reaction of the gas, damage of the member by the by-products and the like occur.

Since a temperature in the transfer space (transfer chamber) 203 is not controlled when the process chamber 201 and the transfer chamber 203 are cleaned, the process chamber 201 and the transfer chamber 203 are difficult to be easily cleaned. For example, a film having the same characteristic as the film formed on the wafer 200 is formed on a wall of the process chamber 201. However, since a temperature in the transfer chamber 203 is lower than a temperature of an atmosphere in the process chamber 201, a film having a different characteristic from that of the process chamber 201 is formed in the transfer chamber 203. Therefore, it is necessary for a cleaning condition of the process chamber 201 to be different from a cleaning condition of the transfer chamber 203. Since a characteristic of the film formed on the wall of the process chamber 201 is the same as that of the film formed on the wafer 200, adjustment of an optimal condition of a cleaning process is relatively easy. However, since a temperature of the film formed on the transfer chamber 203 is not controlled, there is a problem in that the adjustment of the optimal condition of the cleaning process is relatively difficult.

Thus, in the present embodiment, a first thermal insulating unit 10 is installed above the gate valve 1490 formed on the side surface of the lower container 202b. The first thermal insulating unit 10 is installed under the partition 204 to be described below in a Z-axis direction (height direction). Extensions of the lower container 202b in the X-axis direction, the Y-axis direction and the Z-axis direction may be suppressed by installing the first thermal insulating unit 10 and a second thermal insulating unit 20 to be described below. The above-described problems may be addressed by respectively installing heaters in the process chamber 201 and the transfer chamber 203 and independently controlling the temperatures in the process chamber 201 and the transfer chamber 203. Specifically, a characteristic of a film formed in the process chamber 201 and a characteristic of a film formed in the transfer chamber 203 may be respectively controlled by independently controlling the temperature in the process chamber 201 and the temperature in the transfer chamber 203. Alternatively, a cleaning condition of the film formed in the process chamber 201 and a cleaning condition of the film formed in the transfer chamber 203 may be easily adjusted.

The first thermal insulating unit 10 may be formed of, for example, a material having a low thermal conductivity, which is any one of materials such as a heat-resistant resin, a dielectric resin, quartz and graphite or a combination thereof and may have a ring shape.

A substrate support 210 which supports the wafer 200 is installed in the process chamber 201. The substrate support 210 includes a placement surface 211 on which the wafer 200 is placed and a substrate placement unit 212 having an outer circumferential surface 215 on a surface thereof. Preferably, a heater 213 serving as a heating unit is installed in the substrate support 210. The heating unit heats the substrate by installing the heating unit, and thus the quality of the film formed on the substrate may be improved. Through-holes 214 through which the lift pins 207 pass may be installed in the substrate placement unit 212 at positions corresponding to each of the lift pins 207. A height of the placement surface 211 formed on a surface of the substrate placement unit 212 may be lower than that of the outer circumferential surface 215 by as much as a thickness of the wafer 200. With this configuration, a difference between a height of an upper surface of the wafer 200 and a height of the outer circumferential surface 215 of the substrate placement unit 212 is reduced, and thus a turbulent flow of the gas caused by the difference between the heights may be suppressed. When the turbulent flow of the gas does not impact on the processing uniformity of the wafer 200, the outer circumferential surface 215 may be at a higher level than the placement surface 211.

The substrate placement unit 212 is supported by a shaft 217. The shaft 217 passes through a bottom portion of the process container 202 and is connected to a lifting mechanism 218 outside the process container 202. When the shaft 217 and the substrate placement unit 212 are lifted by operating the lifting mechanism 218, the wafer 200 placed on the substrate placement surface 211 may be lifted. The vicinity of a lower end of the shaft 217 is covered with a bellows 219, and thus the process chamber 201 is air-tightly maintained. The second thermal insulating unit 20 is installed between the shaft 217 and the substrate placement unit 212. The second thermal insulating unit 20 suppresses transmitting of heat from the heater 213 to the shaft 217 or the transfer chamber 203. Preferably, the second thermal insulating unit 20 is installed at a higher level than the gate valve 1490. More preferably, a diameter of the second thermal insulating unit 20 is smaller than that of the shaft 217. Accordingly, the transmitting of heat from the heater 213 to the shaft 217 may be suppressed and the temperature uniformity of the substrate placement unit 212 may be improved. A reflection unit 30 which reflects heat from the heater 213 is installed under the substrate placement unit 212 and on the second thermal insulating unit 20, that is, below the heater 213 and on the second thermal insulating unit 20.

Since the reflection unit 30 is installed on the second thermal insulating unit 20, radiant heat from the heater 213 may be reflected without being emitted to an inner wall of the lower container 202b. A reflection efficiency may be improved and an efficiency in which the heater 213 heats the substrate 200 may be improved. When the reflection unit 30 is installed under the second thermal insulating unit 20, since the radiant heat from the heater 213 is absorbed by the second thermal insulating unit 20, an amount of the radiant heat reflected to the heater 213 is reduced and the efficiency in which the heater 213 heats the substrate 200 is reduced. The heating of the second thermal insulating unit 20 and the heating of the shaft 217 by the second thermal insulating unit 20 may be suppressed by installing the reflection unit 30 on the second thermal insulating unit 20.

When the wafer 200 is transferred, the substrate placement unit 212 is lowered so that the substrate placement surface 211 is located at the substrate loading and unloading port 1480 (wafer transfer position). As illustrated in FIG. 1, when the wafer 200 is processed, the substrate placement unit 212 is lifted so that the wafer 200 is located at a process position (wafer process position) in the process chamber 201.

Specifically, when the substrate placement unit 212 is lowered to the wafer transfer position, upper ends of the lift pins 207 protrude from an upper surface of the substrate placement surface 211 and the lift pins 207 support the wafer 200 from thereunder. When the substrate placement unit 212 is lifted to the wafer process position, the lift pins 207 are buried from the upper surface of the substrate placement surface 211 and the substrate placement surface 211 supports the wafer 200 from thereunder. Since the lift pins 207 are directly in contact with the wafer 200, the lift pins 207 are preferably formed of a material such as quartz or alumina. At the process position, the first thermal insulating unit 10 is installed above the gate valve 1490 and is installed at a higher level than the second thermal insulating unit 20.

The first thermal insulating unit 10 may be installed in the vicinity of the exhaust port 221 to be described below. According to this configuration, since a high-temperature gas is introduced into the exhaust port 221, the heating of various portions through walls constituting the process container 202, the transfer chamber 203 or the like may be suppressed when the vicinity of the exhaust port 221 is insulated.

The temperatures in the process chamber 201 and the transfer chamber 203 may be independently and easily controlled by installing the thermal insulating units 10 and 20 in this manner.

A second heating unit 300 (transfer chamber heating unit) for heating the inside of the transfer chamber 203 is installed at the inner wall of the lower container 202b in which the first thermal insulating unit 10 is installed.

A deposition preventing part 302 formed of the same material as the member constituting the process chamber 201 may be installed on a surface of an inner wall of the transfer chamber 203. When a material of the deposition preventing part 302 is quartz the same as the process chamber 201, the same cleaning gas may be used for cleaning the process chamber 201 and the transfer chamber 203. The deposition preventing part 302 may be installed on a surface of the lower container 202b in a film form. The deposition preventing part 302 may include a member having a plate shape.

A temperature adjusting unit 314 may be installed in the transfer chamber 203. The temperature adjusting unit 314 includes at least one of a side temperature adjusting unit 314a and a bottom temperature adjusting unit 314b. Respective portions (side portions or a bottom portion) of the transfer chamber 203 may be heated to have a uniform temperature by installing the temperature adjusting unit 314. As the transfer chamber 203 is heated by combining the temperature adjusting unit 314 and the second heating unit 300, the transfer chamber 203 may be uniformly heated and an amount of a gas adsorbed on the respective portions may be uniform. The side temperature adjusting unit 314a is installed to surround the transfer chamber 203. For example, the side temperature adjusting unit 314a includes a pipe having a spiral shape. The bottom temperature adjusting unit 314b is installed at a bottom portion of the transfer chamber 203. For example, the bottom temperature adjusting unit 314b includes a pipe having a spiral shape to surround a portion of the shaft 217. The side portion or the bottom portion of the transfer chamber 203 may be adjusted to have a predetermined temperature by supplying a temperature adjusting medium into the pipe of the temperature adjusting unit 314 through a medium supply unit 314c. The temperature adjusting medium may include, for example, an insulating thermal medium and specifically, may include an ethylene glycol-based thermal medium or a fluorine-based thermal medium. A temperature of the temperature adjusting unit 314 is adjusted by a medium supplied through the medium supply unit 314c and the medium supply unit 314c is controlled by a controller 260. In a film forming process to be described below, the transfer chamber 203 may be heated to a temperature or more in which at least one of a first gas and a second gas is not adsorbed. More preferably, the transfer chamber 203 is maintained at a temperature or less in which at least one of the first gas and the second gas is not decomposed. More preferably, the transfer chamber 203 is maintained at a temperature or more in which at least one gas of the first gas and the second gas having a larger adsorption amount per unit area is not adsorbed or at a temperature or less in which the gas is not decomposed. In a cleaning process to be described below, the temperature of the wall of the transfer chamber 203 may be increased by stopping supply of a coolant to the temperature adjusting unit 314. A temperature of the side temperature adjusting unit 314a may be different from a temperature of the bottom temperature adjusting unit 314b. For example, the temperature of the side temperature adjusting unit 314a may be higher than that of the bottom temperature adjusting unit 314b. The excessive adsorption of the gas to the side portion (side wall portion) may be suppressed by setting the temperatures in this manner, and an adsorption amount of the gas to the side portion or the bottom portion of the transfer chamber 203 may be uniformly adjusted.

### (Exhaust System)

The exhaust port 221 which exhausts the atmosphere in the process chamber 201 is installed at an upper portion of a side wall of the process chamber 201 [upper container 202a]. An exhaust pipe 224 serving as a first exhaust pipe is connected to the exhaust port 221. A pressure regulator 227 such as an automatic pressure controller (APC) which controls an inner pressure of the process chamber 201 and a vacuum pump 223 are sequentially connected to the exhaust pipe 224 in series. A first exhaust unit (first exhaust line) includes the exhaust port 221, the exhaust pipe 224 and the pressure regulator 227. The first exhaust unit may further include the vacuum pump 223.

A shower head exhaust port 240 which exhausts an atmosphere in a buffer space 232 is installed at an upper portion of the shower head 234. An exhaust pipe 236 serving as a second exhaust pipe is connected to the shower head exhaust port 240. A valve 237, a pressure regulator 238 such as an APC which controls an inner pressure of the buffer space 232 and a vacuum pump 239 are sequentially connected to the exhaust pipe 236 in series. A second exhaust unit (second exhaust line) includes the shower head exhaust port 240, the valve 237, the exhaust pipe 236 and the pressure regulator 238. The second exhaust unit may further include the vacuum pump 239. The exhaust pipe 236 may be connected to the vacuum pump 223 without installing the vacuum pump 239.

A transfer chamber exhaust port 304 which exhausts an atmosphere in the transfer chamber 203 is installed at a lower portion of the side wall of the transfer chamber 203. An exhaust pipe 306 serving as a third exhaust pipe is connected to the transfer chamber exhaust port 304. A valve 308, a pressure regulator 310 such as an APC which controls an inner pressure of the transfer chamber 203 and a vacuum pump 312 are sequentially connected to the exhaust pipe 306 in series. A third exhaust unit (third exhaust line) includes the transfer chamber exhaust port 304, the valve 308, the exhaust pipe 306 and the pressure regulator 310. The third exhaust unit may further include the vacuum pump 312.

### (Gas Inlet Port)

A gas inlet port 241 for supplying various gases into the process chamber 201 is connected to the shower head 234 installed on the process chamber 201. A configuration of a gas supply unit connected to the gas inlet port 241 will be described below.

### (Gas Distribution Unit)

The shower head 234 includes the buffer space 232, the distribution plate 234b, distribution holes 234a and a distribution plate heater 234c. The shower head 234 is installed between the gas inlet port 241 and the process chamber 201. A gas introduced from the gas inlet port 241 is supplied into the buffer space 232 of the shower head 234. The shower head 234 is manufactured of, for example, a material such as quartz, alumina, stainless steel and aluminum. The distribution plate heater 234c is a first heating unit and heats the inside of the process chamber 201. The distribution plate heater 234c is heated by supplying energy such as alternating current (AC) power or electromagnetic waves to the distribution plate heater 234c.

A cover 231 of the shower head 234 may be formed of a conductive metal and may act as an activation unit (excitation unit) for exciting a gas in the buffer space 232 or the process chamber 201. In this case, an insulating block 233 is installed between the cover 231 and the upper container 202a to insulate the cover 231 from the upper container 202a. A matching unit 251 and a high-frequency power source 252 may be connected to an electrode [cover 231] serving as an activation unit to supply electromagnetic waves (high-frequency power or microwave).

A rectifying plate 253 is installed in the buffer space 232 in order to diffuse a gas introduced through the gas inlet port 241 to the buffer space 232.

A gas guide 235 is installed between the rectifying plate 253 and the cover 231. A gas exhaust flow path 258 which exhausts a gas from the buffer space 232 to the shower head exhaust port 240 is formed by the rectifying plate 253 and the gas guide 235.

A cover heater 272 which heats the gas guide 235, the rectifying plate 253 or the like may be installed in the cover 231.

### (Process Gas Supply Unit)

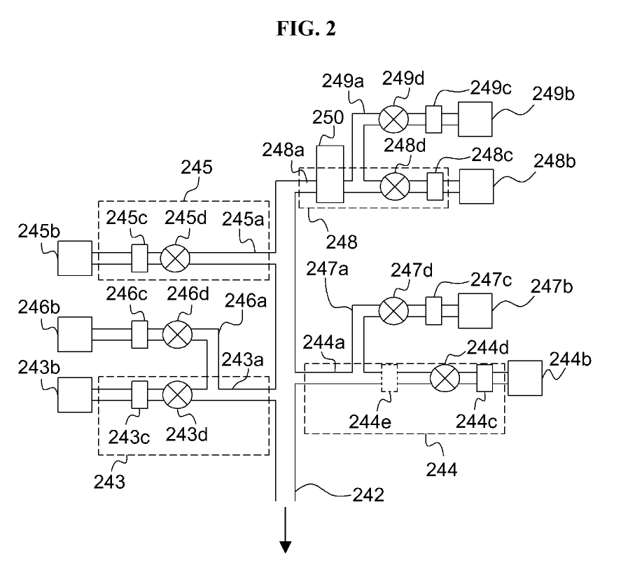

A common gas supply pipe 242 is connected to the gas inlet port 241 connected to the rectifying plate 253. As illustrated in FIG. 2, a first gas supply pipe 243a, a second gas supply pipe 244a, a third gas supply pipe 245a and a cleaning gas supply pipe 248a are connected to the common gas supply pipe 242.

A first-element-containing gas (first process gas) is supplied by a first gas supply unit 243 including the first gas supply pipe 243a and a second-element-containing gas (second process gas) is supplied by a second gas supply unit 244 including the second gas supply pipe 244a. A purge gas is supplied by a third gas supply unit 245 including the third gas supply pipe 245a and a cleaning gas is supplied by a cleaning gas supply unit 248 including the cleaning gas supply pipe 248a. A process gas supply unit which supplies a process gas includes at least one of a first process gas supply unit and a second process gas supply unit, and the process gas includes at least one of a first process gas and a second process gas.

### (First Gas Supply Unit)

A first gas supply source 243b, a mass flow controller (MFC) 243c serving as a flow rate controller (flow rate control unit) and a valve 243d serving as an opening and closing valve are sequentially installed in the first gas supply pipe 243a from an upstream side to a downstream side.

A gas containing a first element (first process gas) is supplied from the first gas supply source 243b. The first process gas is supplied into the gas buffer space 232 through the MFC 243c and the valve 243d, which are installed in the first gas supply pipe 243a, the first gas supply pipe 243a and the common gas supply pipe 242.

The first process gas is a source gas, that is, one of process gases. The first element may include silicon (Si). That is, the first process gas may be a silicon-containing gas. The silicon-containing gas includes dichlorosilane (SiH₂Cl₂:DCS) gas. A first process gas source may be any one of a solid, a liquid and a gas at room temperature and normal pressure. When the first process gas source is a liquid at room temperature and normal pressure, a vaporizer (not illustrated) may be installed between the first gas supply source 243b and the MFC 243c. In this specification, an example in which the first process gas is a gas will be described.

A downstream end of a first inert gas supply pipe 246a is connected to a downstream side of the valve 243d of the first gas supply pipe 243a. An inert gas supply source 246b, an MFC 246c and a valve 246d are sequentially installed in the first inert gas supply pipe 246a from an upstream side to a downstream side.

In the present embodiment, an inert gas may include nitrogen (N₂) gas. In addition to the N₂ gas, rare gases such as helium (He) gas, neon (Ne) gas, and argon (Ar) gas may be used as the inert gas.

A first-element-containing gas supply unit 243 (also referred to as a silicon-containing gas supply unit) includes the first gas supply pipe 243a, the MFC 243c and the valve 243d.

The first-element-containing gas supply unit 243 may further include the first gas supply source 243b and a first inert gas supply unit.

The first inert gas supply unit includes the first inert gas supply pipe 246a, the MFC 246c and the valve 246d. The first inert gas supply unit may further include the inert gas supply source 246b and the first gas supply pipe 243a.

### (Second Gas Supply Unit)

A second gas supply source 244b, an MFC 244c and a valve 244d are sequentially installed in the second gas supply pipe 244a from an upstream side to a downstream side.

A gas containing a second element (hereinafter referred to as a “second process gas”) is supplied through the second gas supply source 244b. The second process gas is supplied into the buffer space 232 through the MFC 244c and the valve 244d, which are installed in the second gas supply pipe 244a, the second gas supply pipe 244a and the common gas supply pipe 242.

The second process gas is one of process gases. The second process gas may be considered as a reaction gas or a modifying gas.

The second process gas contains a second element different from the first element. The second element includes, for example, oxygen (O), nitrogen (N), carbon (C) or hydrogen (H). In the present embodiment, the second process gas includes, for example, a nitrogen-containing gas. Specifically, ammonia (NH₃) gas is used as a nitrogen-containing gas. The second process gas is a gas of which an adsorption amount per unit area is greater than that of the first process gas.

The second gas supply unit 244 includes the second gas supply pipe 244a, the MFC 244c and the valve 244d.

A remote plasma unit (RPU) 244e serving as an activation unit may be further installed. The RPU 244e activates the second process gas.

A downstream end of a second inert gas supply pipe 247a is connected to a downstream side of the valve 244d of the second gas supply pipe 244a. An inert gas supply source 247b, an MFC 247c and a valve 247d are sequentially installed in the second inert gas supply pipe 247a from an upstream side to a downstream side.

An inert gas is supplied into the buffer space 232 through the MFC 247c and the valve 247d, which are installed in the second inert gas supply pipe 247a, and the second inert gas supply pipe 247a. The inert gas acts as a carrier gas or a dilution gas in a thin film forming process [processes S203 to S207 to be described below].

A second inert gas supply unit includes the second inert gas supply pipe 247a, the MFC 247c and the valve 247d. The second inert gas supply unit may further include the inert gas supply source 247b and the second gas supply pipe 244a.

A second-element-containing gas supply unit 244 may further include the second gas supply source 244b and the second inert gas supply unit.

### (Third Gas Supply Unit)

A third gas supply source 245b, an MFC 245c and a valve 245d are sequentially installed in the third gas supply pipe 245a from an upstream side to a downstream side.

An inert gas serving as a purge gas is supplied from the third gas supply source 245b. The inert gas is supplied into the buffer space 232 through the MFC 245c and the valve 245d, which are installed in the third gas supply pipe 245a, the third gas supply pipe 245a and the common gas supply pipe 242.

In the present embodiment, the inert gas is, for example, nitrogen (N₂) gas. In addition to the N₂ gas, a rare gas such as helium (He) gas, neon (Ne) gas and argon (Ar) gas may be used as the inert gas.

The third gas supply unit 245 (referred to as a purge gas supply unit) includes the third gas supply pipe 245a, the MFC 245c and the valve 245d.

### (First Cleaning Gas Supply Unit)

A cleaning gas source 248b, an MFC 248c, a valve 248d and an RPU 250 are sequentially installed in the cleaning gas supply pipe 248a from an upstream side to a downstream side.

A cleaning gas is supplied from the cleaning gas source 248b. The cleaning gas is supplied into the gas buffer space 232 through the MFC 248c, the valve 248d and the RPU 250, which are installed in the cleaning gas supply pipe 248a, the cleaning gas supply pipe 248a and the common gas supply pipe 242.

A downstream end of a fourth inert gas supply pipe 249a is connected to a downstream side of the valve 248d of the cleaning gas supply pipe 248a. A fourth inert gas supply source 249b, an MFC 249c and a valve 249d are sequentially installed in the fourth inert gas supply pipe 249a from an upstream side to a downstream side.

A first cleaning gas supply unit includes the cleaning gas supply pipe 248a, the MFC 248c and the valve 248d. The first cleaning gas supply unit may further include the cleaning gas source 248b, the fourth inert gas supply pipe 249a and the RPU 250.

An inert gas supplied from the fourth inert gas supply source 249b is used as a carrier gas or a dilution gas of the cleaning gas.

The cleaning gas supplied from the cleaning gas source 248b removes by-products and the like adhered to the shower head 234 or the process chamber 201 in the cleaning process.

### (Second Cleaning Gas Supply Unit)

A second cleaning gas supply pipe 320 is installed in an upper portion of a side portion of the transfer chamber 203. A cleaning gas source 322, an MFC 324, a valve 326 and an RPU 328 are sequentially installed in the second cleaning gas supply pipe 320 from an upstream side to a downstream side.

A cleaning gas is supplied from the cleaning gas source 322. The cleaning gas is supplied into the transfer chamber 203 through the MFC 324, the valve 326 and the RPU 328, which are installed in the second cleaning gas supply pipe 320, and the cleaning gas supply pipe 320.

A second cleaning gas supply unit includes the cleaning gas supply pipe 320, the MFC 324 and the valve 326. The second cleaning gas supply unit may further include the cleaning gas source 322 and the RPU 328.

The cleaning gas supplied from the cleaning gas source 322 removes by-products and the like adhered to portions such as the inner wall of the transfer chamber 203, the lift pins 207, the shaft 217, a back surface of the substrate support 210 and a back surface of the partition 204 in the cleaning process.

The cleaning gas is, for example, a nitrogen trifluoride (NF₃) gas. The cleaning gas may include hydrogen fluoride (HF) gas, chlorine trifluoride gas (ClF₃) gas, fluorine (F₂) gas and a combination thereof.

More preferably, the above-described MFCs installed in the respective gas supply units may include a component having a high response of gas flow such as a needle valve or orifice. For example, when a gas pulse width is the order of milliseconds, the MFC may not respond, but the needle valve or the orifice may correspond to the gas pulse having milliseconds or less by being combined with a high-speed ON/OFF valve.

### (Control Unit)

As illustrated in FIG. 1, the substrate processing apparatus 100 includes the controller 260 which controls operations of each unit of the substrate processing apparatus 100.

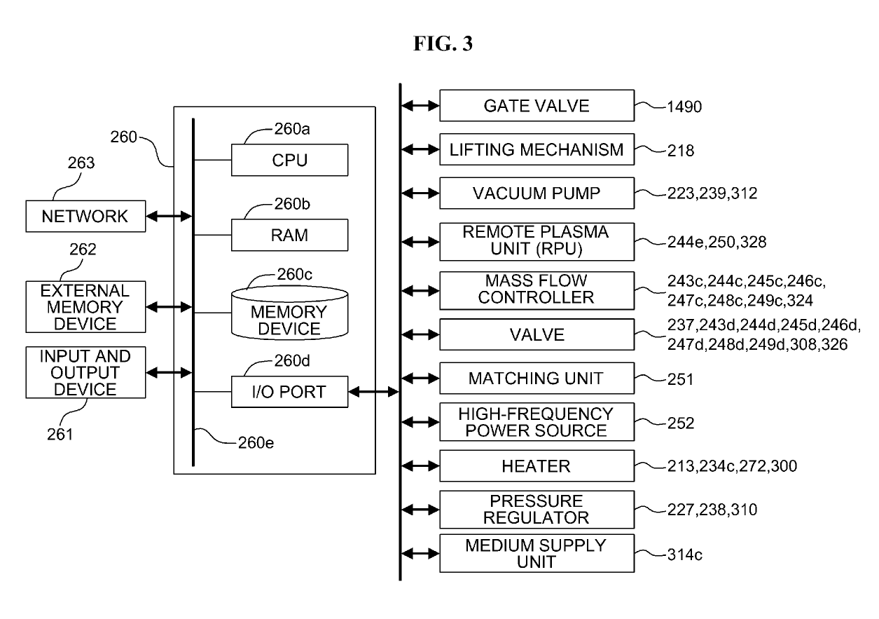

The controller 260 is schematically illustrated in FIG. 3. The controller 260 serving as a control unit (control device) is embodied by a computer including a central processing unit (CPU) 260a, a random access memory (RAM) 260b, a memory device 260c and an input-and-output (I/O) port 260d. The RAM 260b, the memory device 260c and the I/O port 260d may exchange data with the CPU 260a through an internal bus 260e. An I/O device 261 configured as a touch panel or the like and an external memory device 262 may be connected to the controller 260.

The memory device 260c is embodied by, for example, a flash memory and a hard disk drive (HDD). A control program controlling operations of the substrate processing apparatus, a process recipe describing sequences or conditions of substrate processing to be described below, calculation data or process data, which is generated in a process in which a process recipe used in the processing of the wafer 200 is set, or the like are readably stored in the memory device 260c. The process recipe, which is a combination of sequences, causes the controller 260 to execute each sequence in a substrate processing process to be described below in order to obtain a predetermined result, and functions as a program. Hereinafter, the process recipe or the control program and the like are collectively simply called a “program.” When the term “program” is used in this specification, it may refer to either or both of the process recipe and the control program. The RAM 260b functions as a memory area (work area) in which a program, calculation data, process data and the like read by the CPU 260a are temporarily stored.

The I/O port 260d is connected to the gate valve 1490, the lifting mechanism 218, the heaters 213, 234c, 272 and 300, the pressure regulators 227, 238 and 310, the vacuum pumps 223, 239 and 312, the matching unit 251, the high-frequency power source 252, the valves 237, 243d, 244d, 245d, 246d, 247d, 248d, 249d, 308 and 326, the RPUs 244e, 250 and 328, the MFCs 243c, 244c, 245c, 246c, 247c, 248c, 249c and 324 and the medium supply unit 314c.

The CPU 260a serving as a calculating unit reads and executes the control program from the memory device 260c and reads the process recipe from the memory device 260c according to an input of a manipulating command and the like from the I/O device 261. The CPU 260a is configured to compare and calculate the process recipe or the control data stored in the memory device 260c to a preset value input from a receiving unit 285 and obtain calculation data. The CPU 260a is configured to perform the determination of the process data (process recipe) corresponding to the calculation data. The CPU 260a is configured to control an open or close operation of the gate valve 1490, a lifting operation of the lifting mechanism 218, a power supply operation to the heaters 213, 234c, 272 and 300, a pressure regulating operation by the pressure regulators 227 and 238, an ON/OFF operation of the vacuum pumps 223, 239 and 312, a gas activation operation of the RPUs 244e, 250 and 328, an ON/OFF operation of the gas by the valves 237, 243d, 244d, 245d, 246d, 247d, 248d, 249d, 308 and 326, operations of the MFCs 243c, 244c, 245c, 246c, 247c, 248c, 249c and 324, a matching operation of the power by the matching unit 251, ON/OFF operations of the high-frequency power source 252, a medium supply by the medium supply unit 314c, and the like according to the contents of the read process recipe.

The controller 260 is not limited to being embodied as a dedicated computer, and may be embodied as a general-purpose computer. For example, the controller 260 according to the present embodiment may be embodied by preparing the external memory device 262 [e.g., a magnetic tape, a magnetic disk such as a flexible disk or a hard disk, an optical disc such as a compact disc (CD) or a digital video disc (DVD), a magneto-optical disc such as an MO or a semiconductor memory such as a Universal Serial Bus (USB) memory or a memory card] recording the above-described program and then installing the program in the general-purpose computer using the external memory device 262. A method of supplying the program to the computer is not limited to supplying through the external memory device 262. For example, a communication line such as a network 263 (the Internet or a dedicated line) may be used to supply the program regardless of the external memory device 262. The memory device 260c or the external memory device 262 is configured as a non-transitory computer-readable recording medium. Hereinafter, these are also collectively simply called a recording medium. When the term “recording medium” is used in this specification, it refers to either or both of the memory device 260c and the external memory device 262.

### (2) Substrate Processing Process

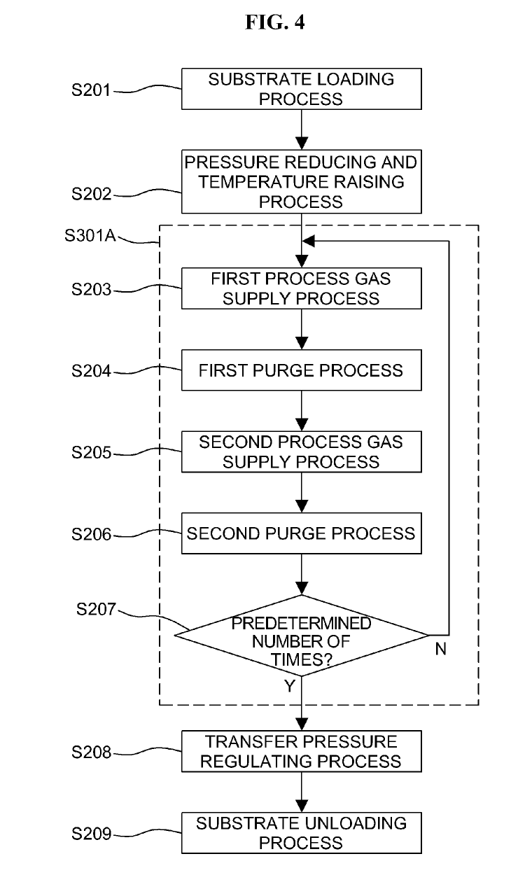

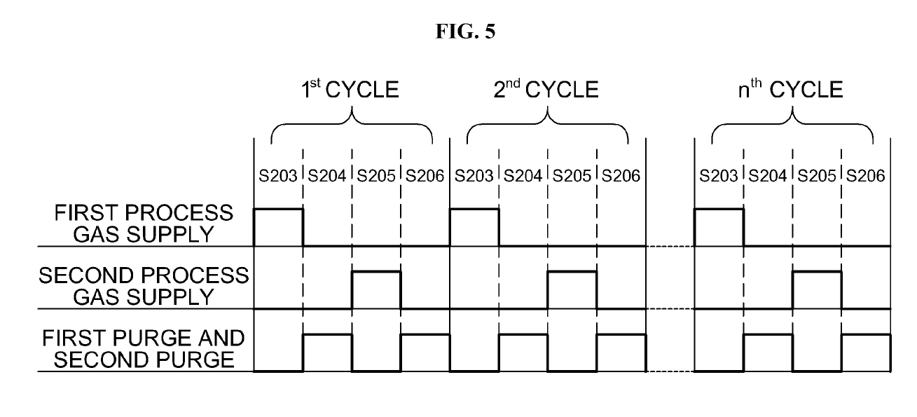

Next, an example of sequences of forming a silicon nitride (SiN) film serving as an insulating film and silicon-containing film on a substrate will be described with reference to FIGS. 4 and 5 as an example of a process of manufacturing a semiconductor device using the above-described substrate processing apparatus. In the following description, operations of each unit of the substrate processing apparatus are controlled by the controller 260.

When the term “wafer” is used in this specification, it refers to “the wafer itself,” or a “laminate (aggregate) of a wafer and a predetermined layer, film and the like formed on a surface thereof,” that is, the wafer refers to a wafer including a predetermined layer, film and the like formed on a surface thereof. When the term “surface of the wafer” is used in this specification, it refers to “a surface (exposed surface) of the wafer itself” or “a surface of a predetermined layer, film and the like formed on the wafer, that is, an outermost surface of the wafer laminate.”

Therefore, when it is described in this specification that “a predetermined gas is supplied to the wafer,” it means that “a predetermined gas is directly supplied to a surface (exposed surface) of the wafer itself” or “a predetermined gas is supplied to a layer, film and the like formed on the wafer, that is, to the outermost surface of the wafer laminate.” When it is described in this specification that “a predetermined layer (or film) is formed on the wafer,” it means that “a predetermined layer (or film) is directly formed on a surface (exposed surface) of the wafer itself” or “a predetermined layer (or film) is formed on a layer, film and the like formed on the wafer, that is, a predetermined layer (or film) is formed on the outermost surface of the wafer laminate.”

The terms “substrate” and “wafer” as used in this specification have the same meanings. Thus, the term “wafer” in the above description may be replaced with the term “substrate.”

Hereinafter, a substrate processing process will be described.

### [Substrate Loading Process (S201)]

First, in the substrate processing process, the wafer 200 is loaded into the process chamber 201. Specifically, the substrate support 210 is lowered by the lifting mechanism 218 and the lift pins 207 protrude from an upper surface of the substrate support 210 through the through-holes 214. After an inner pressure of the process chamber 201 is adjusted to a predetermined pressure, the gate valve 1490 is open. The wafer 200 is placed on the lift pins 207 through an opening of the gate valve 1490. After the wafer 200 is placed on the lift pins 207, the substrate support 210 is lifted by the lifting mechanism 218 to a predetermined position and the wafer 200 is placed on the substrate support 210.

### [Pressure Reducing and Temperature Raising Process (S202)]

Next, the process chamber 201 is exhausted through the process chamber exhaust pipe 224 so that the inner pressure of the process chamber 201 becomes a predetermined degree of vacuum. In this case, a degree of opening of the APC valve serving as the pressure regulator 227 is fed back and controlled based on a pressure value measured by a pressure sensor. An amount of power supply to the heater 213 serving as a first heating unit, the distribution plate heater 234c and the second heating unit 300 is fed back and controlled so that the temperature in the process chamber 201 is higher than the temperature in the transfer chamber 203 based on a temperature measured by a temperature sensor (not illustrated). Specifically, the substrate support 210 is pre-heated by the heater 213 and remains for a predetermined time in the state when a temperature of the wafer 200 or the substrate support 210 is stabilized. During that time, when a gas is emitted from residual material or there is residual moisture in the process chamber 201, the gases may be removed by vacuum exhaustion or purging by supplying N₂ gas. In this manner, the preparation before a film forming process is completed. The process chamber 201 is exhausted so that the inner pressure thereof becomes a degree of vacuum that it can reach at once.

In this case, the temperature of the heater 213 ranges from 200° C. to 750° C., preferably from 300° C. to 600° C. and more preferably from 300° C. to 550° C. A temperature of the distribution plate heater 234c ranges, for example, from 200° C. to 400° C. A temperature of the second heating unit (heater) 300 ranges from a room temperature to 400° C. and preferably from 50° C. to 200° C. Similarly, a thermal medium is supplied so that temperatures of the side temperature adjusting unit 314a and the bottom temperature adjusting unit 314b also range from 50° C. to 200° C. The above-described temperatures are controlled to be maintained in a film forming process (S301A). The above-described temperatures are temperatures in which at least one of a first gas and a second gas is adsorbed on the wafer 200 and more preferably temperatures or more in which at least one of the first gas and the second gas is decomposed on the wafer 200. That is, the above-described temperatures are temperatures at which reactions occur. A temperature of the second heating unit 300 is set to a temperature that interferes with adsorption or decomposition as described above.

### [Film Forming Process (5301A)]

Next, an example in which a SiN film is formed on the wafer 200 will be described. The film forming process (S301A) will be described in detail with reference to FIGS. 4 and 5.

After the wafer 200 is placed on the substrate support 210 and the atmosphere in the process chamber 201 is stabilized, processes S203 to S207 illustrated in FIG. 4 are performed.

### [First Process Gas Supply Process (S203)]

In a first process gas supply process (S203), a silicon-containing gas serving as a first gas (source gas) is supplied by the first gas supply unit 243. The silicon-containing gas may include DCS gas. Specifically, when a gas valve is open, the silicon-containing gas is supplied from a gas source to the substrate processing apparatus 100. In this case, the valve 243d is open and the MFC 243c adjusts a flow rate of the silicon-containing gas to a predetermined value. The silicon-containing gas with the flow rate thereof adjusted is supplied into the process chamber 201 in a reduced pressure state through the buffer space 232 and the distribution holes 234a of the shower head 234. Since the exhaustion of the process chamber 201 is performed by an exhaust system, the inner pressure of the process chamber 201 at this time is a first pressure (e.g., in a range of 100 Pa to 20,000 Pa). That is, the silicon-containing gas is supplied onto the wafer 200 in the process chamber 201 of which the inner pressure is the first pressure. A silicon-containing layer is formed on the wafer 200 by supplying the silicon-containing gas. Here, the silicon-containing layer is a layer containing silicon (Si) or a layer containing silicon and chlorine (Cl).

### [First Purge Process (S204)]

After the silicon-containing layer is formed on the wafer 200, the supply of the silicon-containing gas is stopped. The process chamber 201 is purged by stopping the supply of the source gas (silicon-containing gas) and exhausting the source gas in the process chamber 201 or the source gas in the buffer space 232 through the process chamber exhaust pipe 224.

In the purge process, the purge process may be performed by supplying an inert gas and extruding the residual gas in addition to by simply exhausting (vacuum suction) the gas and discharging the gas. That is, a combination of the vacuum suction and the supply of the inert gas may be performed or the vacuum suction and the supply of the inert gas may be alternately performed.

In this case, the valve 237 of the shower head exhaust pipe 236 is open, and the gas in the buffer space 232 may be exhausted through the shower head exhaust pipe 236. During the exhaustion, inner pressures (exhaustion conductance) of the shower head exhaust pipe 236 and the buffer space 232 are controlled by the pressure regulator 227 and the valve 237. The pressure regulator 227 and the valve 237 may be controlled so that an exhaustion conductance of the shower head exhaust pipe 236 which exhausts the buffer space 232 is greater than an exhaustion conductance of the process chamber exhaust pipe 224 which exhausts the process chamber 201. A gas flow from the gas inlet port 241 which is an end portion of the buffer space 232 toward the shower head exhaust port 240 which is another end portion of the buffer space 232 is formed by adjusting the exhaustion conductance in this manner. Therefore, a gas adhered to a wall of the buffer space 232 or a gas floating in the buffer space 232 may be exhausted through the shower head exhaust pipe 236 without entering the process chamber 201. An inner pressure of the buffer space 232 and the pressure (exhaustion conductance) in the process chamber 201 may be adjusted to suppress a backflow of the gas from the process chamber 201 to the buffer space 232.

In the first purge process (S204), the vacuum pump 223 continuously operates, and the gas in the process chamber 201 is exhausted through the vacuum pump 223. The pressure regulator 227 and the valve 237 may be adjusted so that the exhaustion conductance of the process chamber exhaust pipe 224 which exhausts the process chamber 201 is greater than the exhaustion conductance of the shower head exhaust pipe 236 which exhausts the buffer space 232. In this manner, a gas flow toward the process chamber exhaust pipe 224 via the process chamber 201 is formed by adjusting the pressure regulator 227 and the valve 237 and thus the residual gas in the process chamber 201 may be exhausted.

After a predetermined time has elapsed, a flow path from the buffer space 232 to the shower head exhaust pipe 236 is blocked by stopping the supply of the inert gas and closing the valve 237.

More preferably, after the predetermined time has elapsed, the valve 237 is closed while the vacuum pump 223 continuously operates. In this manner, since the flow toward the process chamber exhaust pipe 224 via the process chamber 201 is not affected by the shower head exhaust pipe 236, the inert gas may be more reliably supplied onto the substrate, and thus the residual gas on the substrate may be more efficiently removed.

Purging the buffer space 232 refers to an extrusion operation of the gas by supplying the inert gas in addition to discharging the gas by simply vacuum suction. Therefore, in the first purge process (S204), the purge process may be performed by supplying the inert gas into the buffer space 232 and extruding the residual gas. That is, a combination of the vacuum suction and the supply of the inert gas may be performed or the vacuum suction and the supply of the inert gas may be alternately performed.

In this case, a flow rate of N₂ gas supplied to the process chamber 201 need not be high, and an amount of the supplied N₂ gas corresponding to a capacity of the process chamber 201 may be sufficient. An effect on a subsequent process may be reduced by performing the purge process in this manner. The inside of the process chamber 201 is partially purged to reduce a purging time, thereby improving the manufacturing throughput. Unnecessary consumption of the N₂ gas may be suppressed to a minimum.

A flow rate of N₂ gas serving as a purge gas supplied through an inert gas supply system in this case ranges from 100 sccm to 20,000 sccm. In addition to the N₂ gas, a rare gas such as Ar, He, Ne and Xe may be used as the purge gas.

### [Second Process Gas Supply Process (S205)]

After the first purge process is performed, a nitrogen-containing gas serving as a second gas (reaction gas) is supplied into the process chamber 201 through the gas inlet port 241 and the plurality of distribution holes 234a. In the present embodiment, ammonia (NH₃) gas is used as the nitrogen-containing gas. Since the second gas is supplied into the process chamber 201 through the distribution holes 234a, the second gas may be uniformly supplied onto the substrate. Therefore, a film thickness may be made uniform. The second gas activated by the RPU serving as an activation unit (excitation unit) may be supplied into the process chamber 201.

In this case, the MFC 244c adjusts a flow rate of the NH₃ gas to a predetermined value. The flow rate of the NH₃ gas ranges from 100 sccm to 10,000 sccm. When the NH₃ gas flows into the RPU, the RPU is turned on (a state in which power is turned on) and the NH₃ gas is activated (excited).

When the NH₃ gas is supplied to the silicon-containing layer formed on the wafer 200, the silicon-containing layer is modified. Therefore, a modified layer containing silicon atoms or a modified layer containing silicon atoms and nitrogen atoms is formed. A number of modified layers may be formed by supplying the NH₃ gas activated by the RPU onto the wafer 200.

The modified layer has, for example, a predetermined thickness, a predetermined distribution and a predetermined penetration depth of a nitrogen component with respect to the silicon-containing layer according to the inner pressure of the process chamber 201, the flow rate of the NH₃ gas, the temperature of the wafer 200 and a power supply state of the RPU.

After a predetermined time has elapsed, the supply of the NH₃ gas is stopped.

When the silicon-containing layer is modified by supplying the NH₃ gas, by-products such as ammonium chloride (NH₄Cl) or hydrogen chloride (HCl) are generated. The above-described by-products generated in the transfer chamber 203 or a film deposited in the transfer chamber 203 are assumed to be the same material as these materials, a combination thereof or a material in which these materials react with at least one of the first gas and the second gas.

### [Second Purge Process (S206)]

A second purge process (S206) is performed by exhausting the NH₃ gas in the process chamber 201 or the NH₃ gas in the buffer space 232 through the first exhaust unit after the supply of the NH₃ gas is stopped. The second purge process (S206) is performed in the same manner as the first purge process (S204).

In the second purge process (S206), the vacuum pump 223 continuously operates and the gas in the process chamber 201 is exhausted through the process chamber exhaust pipe 224. The pressure regulator 227 and the valve 237 may be adjusted so that the exhaustion conductance from the process chamber 201 to the process chamber exhaust pipe 224 is greater than the exhaustion conductance to the buffer space 232. In this manner, a gas flow toward the process chamber exhaust pipe 224 via the process chamber 201 may be formed by adjusting the pressure regulator 227 and the valve 237 and thus the residual gas in the process chamber 201 may be exhausted. The inert gas may be reliably supplied onto the substrate by supplying the inert gas, and thus the removal efficiency of the residual gas on the substrate may be improved.

After a predetermined time has elapsed, the supply of the inert gas is stopped, the valve 237 is closed, and thus a space between the buffer space 232 and the shower head exhaust pipe 236 is blocked.

More preferably, after the predetermined time has elapsed, the valve 237 is closed while the vacuum pump 223 continuously operates. With this configuration, since the flow toward the shower head exhaust pipe 236 via the process chamber 201 is not affected by the process chamber exhaust pipe 224, the inert gas may be reliably supplied onto the substrate and the removal efficiency of the residual gas on the substrate may be further improved.

Purging the atmosphere in the process chamber 201 includes an extrusion operation of the gas by supplying the inert gas in addition to discharging the gas by simply vacuum suction. That is, a combination of the vacuum suction and the supply of the inert gas may be performed or the vacuum suction and the supply of the inert gas may be alternately performed.

In this case, a high flow rate of N₂ gas supplied into the process chamber 201 is unnecessary, and an amount of the supplied N₂ gas corresponding to the capacity of the process chamber 201 may be sufficient. In this case, a high flow rate of N₂ gas supplied into the process chamber 201 is unnecessary, and an amount of the supplied N₂ gas corresponding to the capacity of the process chamber 201 may be sufficient. An effect on a subsequent process may be reduced by performing the purge process in this manner. The inside of the process chamber 201 is partially purged to reduce a purging time, thereby improving the manufacturing throughput. Unnecessary consumption of the N₂ gas may be suppressed to a minimum.

A flow rate of the N₂ gas serving as a purge gas supplied through an inert gas supply system in this case ranges from 100 sccm to 20,000 sccm. The purge gas is the same as the above-described purge gas.

### [Determination Process (S207)]

After the second purge process (S206) is completed, the controller 260 determines whether or not processes S203 to S206 in the film forming process (S301A) are performed a predetermined number n of times (where n is a natural number) (S207). That is, the controller 260 determines whether a film having a desired thickness is formed on the wafer 200. An insulating film containing silicon and nitrogen, that is, a SiN film, may be formed on the wafer 200 by performing a cycle including the above-described processes S203 to S206 at least once. Preferably, the above-described cycle is repeated. Thus, the SiN film having a predetermined thickness is formed on the wafer 200.

When the predetermined number of times are not performed (when N is determined in S207), the cycle of processes S203 to S206 is repeated. When the predetermined number of times are performed (when Y is determined in S207), the film forming process (S301A) is completed and a transfer pressure regulating process (S208) and a substrate unloading process (S209) are performed.

### [Transfer Pressure Regulating Process (S208)]

In the transfer pressure regulating process (S208), the process chamber 201 and the transfer chamber 203 are exhausted through the process chamber exhaust pipe 224 and the transfer chamber exhaust port 304, respectively so that the inner pressure of the process chamber 201 or the inner pressure of the transfer chamber 203 becomes a predetermined degree of vacuum. In this case, the inner pressure of the process chamber 201 or the inner pressure of the transfer chamber 203 is adjusted to be equal to or lower than the inner pressure of a vacuum transfer chamber 1400. The wafer 200 may remain on the lift pins 207 during, before or after the transfer pressure regulating process (S208) so that it is cooled to a predetermined temperature.

### [Substrate Unloading Process (S209)]

After the inner pressure of the process chamber 201 and the inner pressure of the transfer chamber 203 have a predetermined degree of vacuum in the transfer pressure regulating process (S208), the gate valve 1490 is open and the wafer 200 is unloaded from the transfer chamber 203 into the vacuum transfer chamber 1400.

The wafer 200 is processed through these processes.

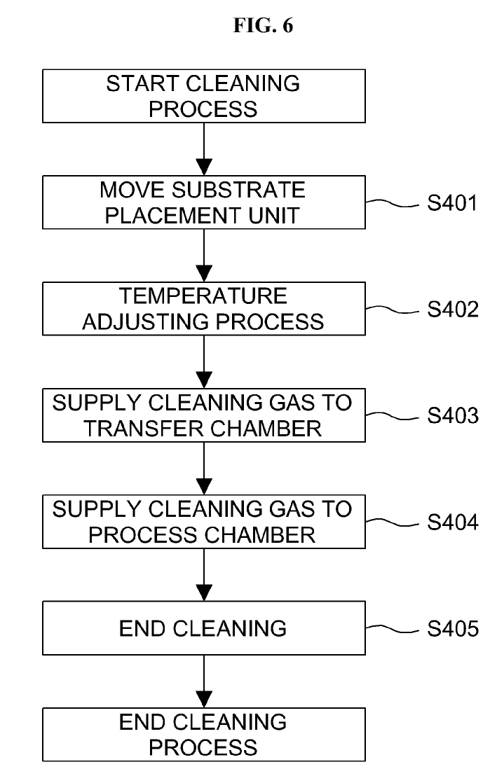

Next, a cleaning process will be described with reference to FIG. 6.

In the present embodiment, when cleaning is simultaneously performed while the process chamber 201 communicates with the transfer chamber 203, since a cleaning gas is supplied from an upper portion of the shower head 234, a concentration of an etchant in the process chamber 201 is greater than a concentration of an etchant which contributes to cleaning the transfer chamber 203. As a result, when the cleaning of the side portion of the transfer chamber 203 is completed, there is a problem in that a peripheral portion of the process chamber 201 is over-etched and a member thereof is degraded. When the cleaning is separately performed without communication between the process chamber 201 and the transfer chamber 203, there is a problem in that the cleaning gas moves from one space to another space and a member in the other space is degraded. These problems may be addressed through the cleaning process to be described below.

### [Substrate Placement Unit Movement Process (S401)]

First, in the cleaning process, the substrate placement unit 212 is lifted by the lifting mechanism 218 and moves to the partition 204 which divides the process chamber 201 and the transfer chamber 203. In this case, a wafer for cleaning (dummy wafer) may be placed on the substrate placement unit 212. The dummy wafer suppresses the over-etching of the placement surface 211 caused by the supply of the cleaning gas to the placement surface 211 of the substrate placement unit 212.

### [Temperature Adjusting Process (S402)]

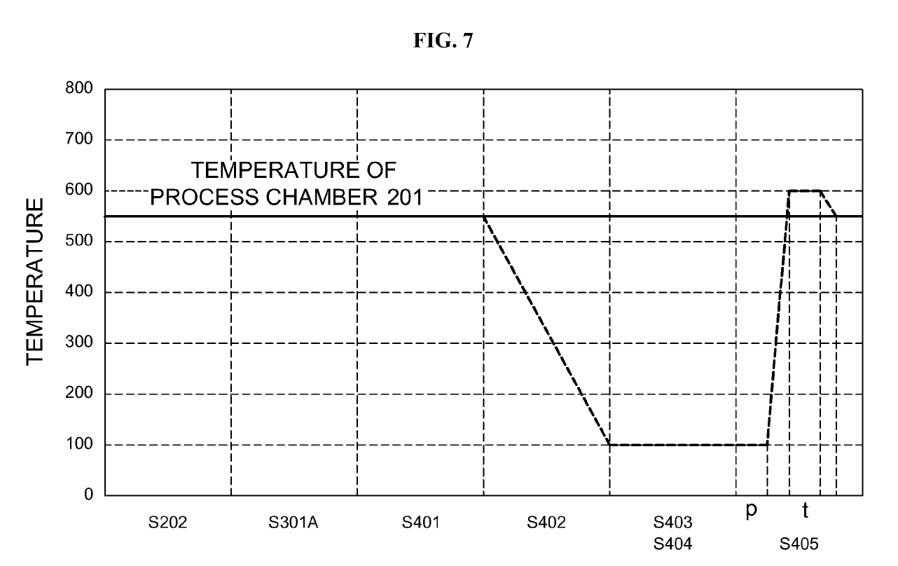

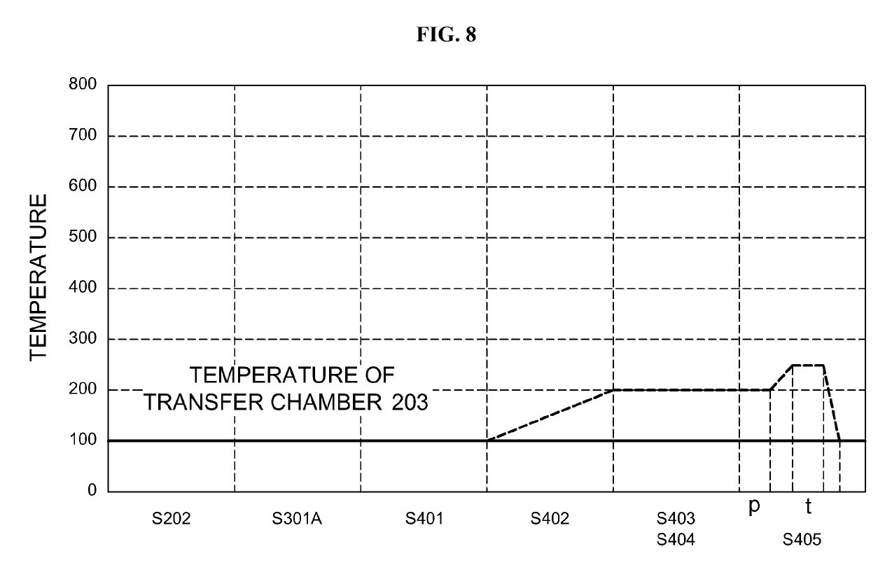

Next, the heater 213 serving as the first heating unit, the distribution plate heater 234c and the second heating unit 300 are controlled so that the temperatures of the process chamber 201 and the transfer chamber 203 become a predetermined temperature. In a cleaning process performed while a conventional substrate processing process is repeated, the temperature in the film forming process (S301A) maintains as solid lines illustrated in FIGS. 7 and 8. In a cleaning process performed between a plurality of batches, the controller 260 may control the second heating unit 300 in the transfer chamber 203, the heater 213 serving as the first heating unit which heats the process chamber 201 and the distribution plate heater 234c so that the temperature in the transfer chamber 203 is higher than the temperature in the process chamber 201 as dotted lines illustrated in FIGS. 7 and 8. By adjusting the temperature in the transfer chamber 203 higher than the temperature in the process chamber 201, a degree of activity of the cleaning gas in the transfer chamber 203 may be greater than a degree of activity of the cleaning gas in the process chamber 201, and a cleaning time of the transfer chamber 203 may reach a cleaning time of the process chamber 201 even when a thickness of a film deposited in the transfer chamber 203 is large or a film formed on or by-products adhered to the details are removed.

In this case, the temperature of the second heating unit 300 ranges from 200° C. to 750° C., preferably from 300° C. to 600° C. and more preferably from 300° C. to 550° C. The temperature of the distribution plate heater 234c ranges, for example, from 200° C. to 400° C. and the temperature of the heater 213 ranges from 100° C. to 400° C. That is, the temperature in the transfer chamber 203 and the temperature in the process chamber 201 are controlled so that the temperature in the transfer chamber 203 is higher than the temperature in the process chamber 201. Examples of adjusting such temperatures are illustrated in FIGS. 7 and 8.

A movement amount of heat from the process chamber 201 to the transfer chamber 203 is reduced by installing the above-described thermal insulating unit. Thus, the temperature in the transfer chamber 203 may be adjusted without influence from the process chamber 201.

When the temperature in the transfer chamber 203 is increased, the medium supply to the temperature adjusting unit 314 may be stopped. A time of increasing the temperature in the transfer chamber 203 may be reduced by stopping the medium supply to the temperature adjusting unit 314.

### [Cleaning Gas Supply Process (S403)]

In a process of supplying a cleaning gas into the transfer chamber 203 (S403), a cleaning gas is supplied into the transfer chamber 203 through the second cleaning gas supply unit. The cleaning gas is supplied from the cleaning gas source 322. The cleaning gas is supplied into the transfer chamber 203 through the MFC 324, the valve 326 and the RPU 328 which are installed in the cleaning gas supply pipe 320. In this case, the cleaning gas is activated by the RPU 328 and supplied into the transfer chamber 203. Performing a process of supplying a cleaning gas into the process chamber (S404) together may suppress the cleaning gas from moving one space to another. Cleaning reactants generated in the transfer chamber 203 may be suppressed from being penetrated into the process chamber 201 by adjusting the inner pressure of the transfer chamber 203 lower than the inner pressure of the process chamber 201. The cleaning gas may be supplied into corners of the transfer chamber 203 by adjusting the inner pressure of the transfer chamber 203. Specifically, by adjusting the inner pressure of the transfer chamber 203 to a pressure at which the cleaning gas in the transfer chamber 203 becomes a molecular flow, a mean free path of gas molecules is increased and thus the cleaning gas may be sufficiently diffused to spaces of corner portions of the transfer chamber 203. By closing the valve 308 and adjusting the inner pressure of the transfer chamber 203 to a pressure at which the cleaning gas in the transfer chamber 203 becomes a viscous flow, a contact time of gas molecules with a film, by-products or the like in the transfer chamber 203 may be increased and thus the cleaning may be promoted. Molecules of the cleaning gas may also be sufficiently supplied to a side portion 501 of the substrate placement unit 212, a side portion 502 of the second thermal insulating unit 20, the substrate loading and unloading port 1480 and the like, in which the gas molecules in a molecular flow state is difficult to be penetrated. The temperature in the transfer chamber 203 is preferably a temperature at which a time in which the cleaning gas molecules stay in the side portion or the bottom portion is increased. For example, the temperature in the transfer chamber 203 is preferably a temperature at which the cleaning gas molecules are adsorbed on the transfer chamber 203. Thus, the cleaning may be promoted.

Specifically, the cleaning gas is supplied from the cleaning gas source 322 into the transfer chamber 203 by opening the valve 326. In this case, the MFC 324 adjusts a flow rate of the cleaning gas to a predetermined value. The cleaning gas of which the flow rate is adjusted is supplied into the transfer chamber 203. The cleaning gas may include nitrogen trifluoride (NF₃) gas, hydrogen fluoride (HF) gas, chlorine trifluoride (ClF₃) gas, fluorine (F₂) gas and combinations thereof.

### [Cleaning Gas Supply Process (S404)]

In the process of supplying the cleaning gas into the process chamber 201 (S404), a cleaning gas is supplied into the process chamber 201 through the first cleaning gas supply unit. The cleaning gas is supplied from the cleaning gas source 248b. The cleaning gas is supplied into the process chamber 201 through the MFC 248c, the valve 248d, the cleaning gas supply pipe 248a, the common gas supply pipe 242, the gas buffer space 232 and the distribution holes 234a. In this case, the cleaning gas activated by the RPU 250 may be supplied into the transfer chamber 203.

Specifically, the cleaning gas is supplied from the cleaning gas source 248b into the process chamber 201 by opening the valve 248d. In this case, the MFC 248c adjusts a flow rate of the cleaning gas to a predetermined value. The cleaning gas of which the flow rate is adjusted is supplied into the process chamber 201. The cleaning gas may include, for example, nitrogen trifluoride (NF₃) gas, hydrogen fluoride (HF) gas, chlorine trifluoride (ClF₃) gas, fluorine (F₂) gas and combinations thereof.

Cleaning gas species used in the process of supplying the cleaning gas into the transfer chamber (S403) and the process of supplying the cleaning gas into the process chamber (S404) are preferably gases having the same property. An undesired chemical reaction can be suppressed by using the gas species having the same property even when the cleaning gas moves from one space to another. In order to suppress the introduction of the cleaning gas, a difference between the inner pressure in one space and the inner pressure in another space is preferably reduced. The introduction of the cleaning gas may be suppressed by reducing the pressure difference.

In the process of supplying the cleaning gas into the transfer chamber (S403) and the process of supplying the cleaning gas into the process chamber (S404), after the cleaning gases are supplied for a predetermined time, a cleaning completion process (S405) is performed.

### [Cleaning Completion Process (S405)]

First, in the cleaning completion process (S405), the supply of the cleaning gas is stopped and the residual cleaning gases in the process chamber 201 and the transfer chamber 203 is purged. In this case, the residual cleaning gases may be extruded by supplying an inert gas into the process chamber 201 and the transfer chamber 203 and the residual cleaning gases may extrude reaction products. Exhaustion efficiency may be improved by performing vacuum exhaustion while repeating the supply and stop of the inert gas. Such a purge process may be performed at the beginning of process S405 as illustrated in FIG. 7.

After the gas is sufficiently replaced and exhausted, the temperature in the process chamber 201 is increased in order to perform the above-described film forming process S301A. The temperature in the transfer chamber 203 is adjusted on the basis of the film forming process S301A. When the transfer chamber 203 is heated as the dotted line illustrated in FIG. 8, the cooling of the transfer chamber 203 is performed. When the transfer chamber 203 is cooled, a cooling time may be reduced by supplying a coolant to the temperature adjusting unit 314.

After the sufficient purging, the temperature in the process chamber 201 may be maintained at a temperature higher than the temperature for a predetermined time before the temperature in the process chamber 201 is adjusted to the temperature in the above-described pressure reducing and temperature raising process S202. For example, the temperature of the heater 213 is adjusted to range from 300° C. to 800° C., preferably from 400° C. to 700° C. and more preferably from 400° C. to 600° C., the temperature of the distribution plate heater 234c is adjusted to range from 300° C. to 500° C. and the temperature of the second heating unit (heater) 300 is adjusted to range from 300° C. to 500° C. For example, the temperature is maintained as a period “t” in FIG. 7. Here, the temperature of each heater is higher than the temperature in the film forming process S301A by as much as a temperature of 50° C. to 100° C. In this manner, the cleaning gas or the reaction products adsorbed on the inner wall or member of the process chamber 201, the inner wall or member of the transfer chamber 203, or the like and cleaning by-products may be desorbed by maintaining the temperature in the process chamber 201 higher than the temperature in the film forming process S301A, and thus the processing quality of the wafer 200 in the film forming process 301A may be improved. The cleaning by-products are, for example, a fluorine-based material or a halogen-based material, and a material generated by reaction of the above-described cleaning gas, the first gas, the second gas, the by-products, and the like. An amount of the reaction products introduced from the transfer chamber 203 into the process chamber 201 may be reduced while performing the film forming process S301A by maintaining the temperature in the transfer chamber 203 higher than the temperature in the film forming process S301A as the dotted line illustrated in FIG. 8 for a predetermined time, and thus the processing quality of the wafer 200 may be improved. After the period “t” in which the temperatures in the process chamber 201 and the transfer chamber 203 are maintained higher than the temperature in the film forming process S301A, the temperatures in the process chamber 201 and the transfer chamber 203 are adjusted to the temperature in the film forming process S301A. The temperatures may be increased at a period “p” illustrated in FIG. 7.

The cleaning process is performed as described above.

Although the method of forming the film by alternately supplying the source gas and the reaction gas is described, any method in which an amount of gas phase reaction of the source gas and the reaction gas or a generation amount of by-product is within an allowed range may be applied. For example, a method in which a supply timing of the source gas overlaps with a supply timing of the reaction gas may be applied.

Although the film forming process is described, the technique may be applied to other processes. For example, the technique may be applied to diffusion processing, oxidation processing, nitridation processing, oxynitridation processing, reduction processing, oxidation-reduction processing, etching processing, heat processing or the like. For example, the technique may also be applied when plasma oxidation processing or plasma nitridation processing is performed on a substrate surface or a film formed on the substrate using only the reaction gas. The technique may be applied when plasma annealing processing is performed using only the reaction gas.

Although the method of manufacturing the semiconductor device is described above, the technique may be applied to other processes in addition to the process of manufacturing the semiconductor device. For example, the technique may be applied to a process of manufacturing a liquid crystal device, a process of manufacturing solar cells, a process of manufacturing a light-emitting device and a substrate processing process such as a process of processing a glass substrate, a process of processing a ceramic substrate and a process of processing a conductive substrate.

Although an example of the method of forming the silicon nitride film using a silicon-containing gas serving as a source gas and a nitrogen-containing gas serving as a reaction gas is described above, the technique may be applied to other methods of forming the film using other gases. For example, the technique may be applied to an oxygen-containing film, a nitrogen-containing film, a carbon-containing film, a boron-containing film, a metal-containing film or a film containing a plurality of these elements. The other films include, for example, a SiO film, an AlO film, a ZrO film, a HfO film, a HfAlO film, a ZrAlO film, a SiC film, a SiCN film, a SiBN film, a TiN film, a TiC film, a TiAlC film or the like. As the characteristic (adsorption characteristic, leaving characteristic, vapor pressure or the like) of each of the source gas and the reactive gas used to form the film is compared and the supply position or the structure in the shower head 234 is appropriately changed, the same effect may be obtained.

A configuration of the apparatus in which a single-wafer substrate is processed in a single process chamber is described above, but the described system is not limited thereto. The concept may be applied to an apparatus in which a plurality of substrates are disposed in a vertical direction or a horizontal direction.

According to the described technique, reproducibility and stability of a process can be improved even though a substrate processing temperature becomes a high temperature.

1. A substrate processing apparatus comprising:
a process chamber where a substrate is processed;
a substrate support where the substrate is placed, the substrate support being disposed in the process chamber;
a transfer chamber disposed under the process chamber;
a partition dividing the process chamber and the transfer chamber;
a first heating unit disposed in the substrate support and configured to heat the substrate and the process chamber;
a second heating unit disposed at a side wall of the transfer chamber below the partition and configured to heat the side wall of the transfer chamber at a temperature different from those of the substrate and the process chamber;
a process gas supply unit configured to supply a process gas into the process chamber;
a first cleaning gas supply unit configured to supply a first cleaning gas into the process chamber;
a second cleaning gas supply unit configured to supply the first cleaning gas into the transfer chamber; and
a control unit configured to control the first heating unit, the second heating unit, the process gas supply unit, the first cleaning gas supply unit and the second cleaning gas supply unit.

2. The substrate processing apparatus of claim 1, further comprising:
a side temperature adjusting unit disposed at the side wall of the transfer chamber below the partition and configured to heat or cool the side wall of the transfer chamber; and
a bottom temperature adjusting unit disposed below the side temperature adjusting unit at a bottom portion of the transfer chamber and configured to heat or cool the bottom portion of the transfer chamber.

3. The substrate processing apparatus of claim 1, wherein the control unit is further configured to control a temperature of the first heating unit such that the process gas reacts with the substrate, and to control a temperature of the second heating unit such that a temperature of the side wall of the transfer chamber is: equal to or higher than a temperature whereat the process gas is not adsorbed onto the side wall of the transfer chamber; and equal to or lower than a temperature whereat the process gas is not decomposed.

4. The substrate processing apparatus of claim 2, wherein the control unit is further configured to control a temperature of the first heating unit such that the process gas reacts with the substrate, and to control a temperature of the second heating unit such that the process gas is not adsorbed onto the side wall of the transfer chamber and is not decomposed.

5. The substrate processing apparatus of claim 2, further comprising a medium supply unit configured to supply a thermal medium to the side temperature adjusting unit and the bottom temperature adjusting unit,
wherein the control unit is further configured to control the medium supply unit such that a temperature of the side temperature adjusting unit is higher than that of the bottom temperature adjusting unit.

6. The substrate processing apparatus of claim 1, further comprising a first thermal insulating unit disposed within the side wall of the transfer chamber under the partition.

7. The substrate processing apparatus of claim 2, further comprising a first thermal insulating unit disposed within the side wall of the transfer chamber under the partition.

8. The substrate processing apparatus of claim 4, further comprising a first thermal insulating unit disposed within the side wall of the transfer chamber under the partition.

9. The substrate processing apparatus of claim 1, further comprising a second thermal insulating unit disposed between the substrate support and a shaft supporting the substrate support, the second thermal insulating unit having a diameter smaller than that of the shaft.

10. The substrate processing apparatus of claim 2, further comprising a second thermal insulating unit disposed between the substrate support and a shaft supporting the substrate support, the second thermal insulating unit having a diameter smaller than that of the shaft.

11. The substrate processing apparatus of claim 4, further comprising a second thermal insulating unit disposed between the substrate support and a shaft supporting the substrate support, the second thermal insulating unit having a diameter smaller than that of the shaft.

12. The substrate processing apparatus of claim 8, further comprising a second thermal insulating unit disposed between the substrate support and a shaft supporting the substrate support, the second thermal insulating unit having a diameter smaller than that of the shaft.

13. The substrate processing apparatus of claim 1, wherein the control unit is further configured to control the first heating unit, the second heating unit, the process gas supply unit, the first cleaning gas supply unit and the second cleaning gas supply unit such that a temperature of the process chamber is maintained to be higher than that of the transfer chamber while the substrate is processed by supplying the process gas into the process chamber and that the temperature of the transfer chamber is maintained to be higher than that of in the process chamber while the first cleaning gas is supplied into the process chamber and the transfer chamber.

14. The substrate processing apparatus of claim 2, wherein the control unit is further configured to control the first heating unit, the second heating unit, the process gas supply unit, the first cleaning gas supply unit and the second cleaning gas supply unit such that a temperature of the process chamber is maintained to be higher than that of the transfer chamber while the substrate is processed by supplying the process gas into the process chamber and that the temperature of the transfer chamber is maintained to be higher than that of the process chamber while the first cleaning gas is supplied into the process chamber and the transfer chamber.

15. The substrate processing apparatus of claim 4, wherein the control unit is further configured to control the first heating unit, the second heating unit, the process gas supply unit, the first cleaning gas supply unit and the second cleaning gas supply unit such that a temperature of the process chamber is maintained to be higher than that of the transfer chamber while the substrate is processed by supplying the process gas into the process chamber and that the temperature of the transfer chamber is maintained to be higher than that of the process chamber while the first cleaning gas is supplied into the process chamber and the transfer chamber.

16. (canceled)

17. (canceled)

18. The substrate processing apparatus of claim 1, wherein the control unit is further configured to control a temperature of the second heating unit such that the cleaning gas is adsorbed onto the transfer chamber when the first cleaning gas is supplied into the process chamber and the transfer chamber.

19. The substrate processing apparatus of claim 13, wherein the control unit is further configured to control a temperature of the second heating unit such that the cleaning gas is adsorbed onto the transfer chamber when the first cleaning gas is supplied into the process chamber and the transfer chamber.

20. The substrate processing apparatus of claim 2, further comprising a thermal medium supply unit configured to supply a thermal medium to each of the side temperature adjusting unit and the bottom temperature adjusting unit.

21. The substrate processing apparatus of claim 2, wherein the second heating unit is disposed between the side temperature adjusting unit and a surface of the side wall of the transfer chamber.

22. The substrate processing apparatus of claim 2, wherein the side temperature adjusting unit comprises a pipe having a spiral shape to surround the transfer chamber.
